(19) United States
(12) Patent Application Publication
(10) Pub. No.: US 2019/0103460 A1
(43) Pub. Date: Apr. 4, 2019

(54) SEMICONDUCTOR TRANSISTOR DEVICE

(71) Applicant: UNITED MICROELECTRONICS CORP., HSINCHU (TW)

(72) Inventors: Chang-Po Hsiung, Hsinchu City (TW); Ping-Hung Chiang, Hsinchu City (TW); Chia-Lin Wang, Yunlin County (TW); Chia-Wen Lu, Chiayi County (TW); Nien-Chung Li, Hsinchu City (TW); Wen-Fang Lee, Hsinchu City (TW); Chih-Chung Wang, Hsinchu City (TW)

(21) Appl. No.: 15/720,204

(22) Filed: Sep. 29, 2017

(51) Int. Cl. H01L 29/06; H01L 29/10; H01L 29/78

(52) U.S. Cl. CPC H01L 29/0642; H01L 29/1083; H01L 29/7835; H01L 29/1095; H01L 29/7834; H01L 29/0657

(57) ABSTRACT

A semiconductor transistor device is provided. The semiconductor transistor device includes a semiconductor substrate, a gate structure, a first isolation structure, a first doped region, and a first extra-contact structure. The gate structure is disposed on the semiconductor substrate, and the semiconductor substrate has a first region and a second region respectively located on two opposite sides of the gate structure. The first isolation structure and the first doped region are disposed in the first region of the semiconductor substrate. The first extra-contact structure is disposed on the semiconductor structure. The first extra-contact structure is located between the gate structure and the first doped region and penetrating into the first isolation structure in the first region of the semiconductor substrate, and the first doped region is electrically coupled to the first extra-contact structure.

### BACKGROUND

### Technical Field

The present disclosure relates in general to a semiconductor transistor device, and more particularly to a semiconductor transistor device including an extra-contact structure.

### Description of the Related Art

With the developments of semiconductor technology, high voltage devices have been applied to a variety of electronic products in different fields. However, as the feature sizes reduce, new issues have been raised in the functions as well as manufacturing processes of high voltage devices. In order to provide improved high voltage devices and fix these issues, researches and developments in the designs of such devices have been disclosed.

### SUMMARY OF THE INVENTION

The present disclosure is directed to a semiconductor transistor device. According to the embodiments of the present disclosure, the first extra-contact structure is electrically coupled to the first doped region (i.e. drain) and penetrating into the first isolation structure (i.e. shallow trench isolation), such that the number of electron-hole pairs resulted from the relatively high density of electric field distribution at the interface between the shallow trench isolation and the drain region can be reduced, the abnormal current (I_{SUB}) from the drain region to the substrate can thus be reduced, thereby Kirk effect can be prevented, and thus device abnormal functionality can be further prevented.

According to an embodiment of the present disclosure, a semiconductor transistor device is disclosed. The semiconductor transistor device includes a semiconductor substrate, a gate structure, a first isolation structure, a first doped region, and a first extra-contact structure. The gate structure is disposed on the semiconductor substrate, and the semiconductor substrate has a first region and a second region respectively located on two opposite sides of the gate structure. The first isolation structure and the first doped region are disposed in the first region of the semiconductor substrate. The first extra-contact structure is disposed on the semiconductor structure. The first extra-contact structure is located between the gate structure and the first doped region and penetrating into the first isolation structure in the first region of the semiconductor substrate, and the first doped region is electrically coupled to the first extra-contact structure.

The disclosure will become apparent from the following detailed description of the preferred but non-limiting embodiments. The following description is made with reference to the accompanying drawings.

### BRIEF DESCRIPTION OF THE DRAWINGS

FIG. 1A shows a top view of a semiconductor transistor device according to an embodiment of the present disclosure;

FIG. 1B shows a cross-sectional view along the cross-sectional line 1B-1B′ in FIG. 1A;

FIG. 2A shows a top view of a semiconductor transistor device according to another embodiment of the present disclosure;

FIG. 2B shows a cross-sectional view along the cross-sectional line 2B-2B′ in FIG. 2A;

FIG. 3A shows a top view of a semiconductor transistor device according to a further embodiment of the present disclosure;

FIG. 3B shows a cross-sectional view along the cross-sectional line 3B-3B′ in FIG. 3A;

FIG. 4A shows a top view of a semiconductor transistor device according to an additional embodiment of the present disclosure;

FIG. 4B shows a cross-sectional view along the cross-sectional line 4B-4B′ in FIG. 4A;

FIG. 5 shows I_{D}-V_{D} curves of semiconductor transistor devices according to some embodiments and comparative embodiments of the present disclosure;

FIG. 6 shows I_{SUB}-V_{G} curves of semiconductor transistor devices according to some embodiments and comparative embodiments of the present disclosure; and

FIG. 7A to FIG. 7D show electric field distributions of semiconductor transistor devices according to some embodiments and comparative embodiments of the present disclosure.

### DETAILED DESCRIPTION OF THE INVENTION

According to the embodiments of the present disclosure, a semiconductor transistor device is provided. The embodiments are described in details with reference to the accompanying drawings. The details of the embodiments are for exemplification only, not for limiting the scope of protection of the disclosure. Moreover, the identical or similar elements of the embodiments are designated with the same reference numerals. Also, it is also important to point out that the illustrations may not be necessarily be drawn to scale, and that there may be other embodiments of the present disclosure which are not specifically illustrated. Thus, the specification and the drawings are to be regarded as an illustrative sense rather than a restrictive sense. It is to be noted that the drawings are simplified for clearly describing the embodiments, and the details of the structures of the embodiments are for exemplification only, not for limiting the scope of protection of the disclosure. Ones having ordinary skills in the art may modify or change the structures according to the embodiments of the present disclosure.

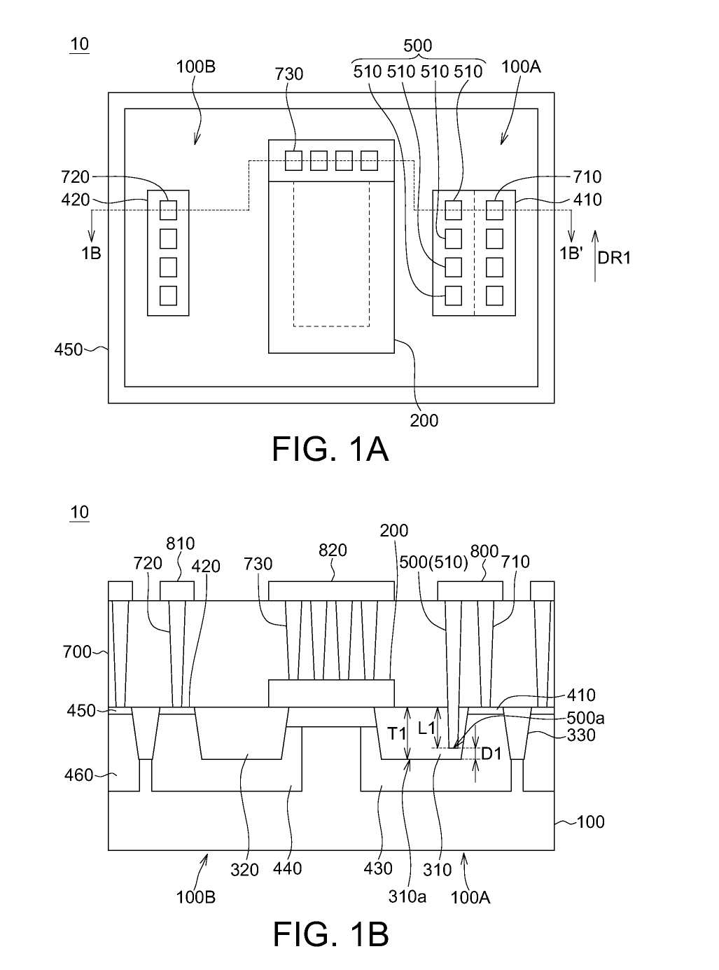

FIG. 1A shows a top view of a semiconductor transistor device according to an embodiment of the present disclosure, and FIG. 1B shows a cross-sectional view along the cross-sectional line 1B-1B′ in FIG. 1A. As shown in FIG. 1A and FIG. 1B, the semiconductor transistor device 10 includes a semiconductor substrate 100, a gate structure 200, a first isolation structure 310, a first doped region 410, and a first extra-contact structure 500. The gate structure 200 is disposed on the semiconductor substrate 100. The semiconductor substrate 100 has a first region 100A and a second region 100B respectively located on two opposite sides of the gate structure 200. The first isolation structure 310 and the first doped region 410 are disposed in the first region 100A of the semiconductor substrate 100. The first extra-contact structure 500 is disposed on the semiconductor structure 100. The first extra-contact structure 500 is located between the gate structure 200 and the first doped region 410, the first extra-contact structure 500 is penetrating into the first isolation structure 310 in the first region 100A of the semiconductor substrate 100, and the first doped region 410 is electrically coupled to the first extra-contact structure 500.

In the embodiments, the first extra-contact structure 500 is electrically isolated from the gate structure 200.

As shown in FIG. 1A and FIG. 1B, the semiconductor transistor device 10 may further include a second isolation structure 320 and a second doped region 420, and the second isolation structure 320 and the second doped region 420 are disposed in the second region 100B of the semiconductor substrate 100.

In the embodiments, the first doped region 410 and the second doped region 420 have a first conductive type; for example, the first conductive type is N-type. In the embodiments, the semiconductor substrate 100 has a second conductive type; for example, the second conductive type is P-type.

In the embodiments, as shown in FIG. 1B, the semiconductor transistor device 10 may further include a third doped region 430 encompassing the first doped region 410 and the first isolation structure 310. In the embodiments, the first doped region 410 and the third doped region 430 have the first conductive type, and a doped concentration of the first doped region 410 is higher than a doped concentration of the third doped region 430.

In the embodiments, as shown in FIG. 1B, the semiconductor transistor device 10 may further include a fourth doped region 440 encompassing the second doped region 420 and the second isolation structure 320. In the embodiments, the second doped region 420 and the fourth doped region 440 have the first conductive type, and a doped concentration of the second doped region 420 is higher than a doped concentration of the fourth doped region 440.

In the embodiments, the first doped region 410 may be drain, the second doped region 420 may be source, the first isolation structure 310 and the second isolation region 320 may be shallow trench isolations (STI), the third doped region 430 and the fourth doped region 440 may be lightly-doped wells, and the semiconductor transistor device 10 is such as a HV FEMOS.

According to the embodiments of the present disclosure, the first extra-contact structure 500 is electrically coupled to the first doped region 410 and penetrating into the first isolation structure 310, such that the number of electron-hole pairs resulted from the relatively high density of electric field distribution at the interface between the shallow trench isolation (i.e. first isolation structure 310) and the drain region (i.e. the first doped region 410 and the third doped region 430) can be reduced, the abnormal current (I_{SUB}) from the drain region to the substrate can thus be reduced, thereby Kirk effect can be prevented, and thus device abnormal functionality can be further prevented.

Particularly, for HV devices with narrow channel widths and shallower STI depths, Kirk effect is easily induced. According to the embodiments of the present disclosure, the first extra-contact structure 500 is electrically coupled to the first doped region 410 (i.e. drain) and penetrating into the first isolation structure 310 (i.e. the STI adjacent to the drain region), such that the first extra-contact structure 500 is extending into the first isolation structure 310 and located adjacent to the drain region (i.e. the first doped region 410 and the third doped region 430), the as-induced electric field distribution, which will be shown in some embodiments hereinafter, is particularly advantageous to the reduction of the abnormal current from the drain to the substrate, thereby preventing Kirk effect.

As shown in FIG. 1B, the semiconductor transistor device 10 may further include a dielectric layer 700 and a metal layer 800, the dielectric layer 700 is disposed on the semiconductor substrate 100, and the metal layer 800 is disposed on the dielectric layer 700. In the embodiments, the first doped region 410 is electrically coupled to the first extra-contact structure 500 through the metal layer 800. As shown in FIG. 1B, the semiconductor transistor device 10 may further include at least a contact plug 710 formed in the dielectric layer 700 which electrically connects the first doped region 410 to the metal layer 800, thereby the first doped region 410 is electrically connected to the first extra-contact structure 500 through the metal layer 800 and the contact plug 710.

As shown in FIG. 1B, in the embodiments, a bottom surface 500a of the first extra-contact structure 500 is embedded in the first isolation structure 310, and the bottom surface 500a is spaced apart from a bottom edge 310a of the first isolation structure 310 by a distance D1 of at least 70 nm. It is important that the first extra-contact structure 500 is embedded in the first isolation structure 310 without penetrating into the third doped region 430, such that the as-induced electric field distribution is most advantageous to the reduction and prevention of Kirk effect. In view of the above, with such distance D1, the first-extra contact structure 500 is extending as deep as possible without penetrating through the bottom edge 310a of the first isolation structure 310.

As shown in FIG. 1B, in the embodiments, a portion of the first extra-contact structure 500 is embedded in the first isolation structure 310, the embedded portion has a first depth L1, the first isolation structure 310 has a first thickness T1, and a ratio (L1/T1) of the first depth L1 to the first thickness T1 is, for example, larger than 0.5 and less than 0.8.

As shown in FIG. 1A, in the embodiments, the first extra-contact structure 500 may include a plurality of first extra-contact plugs 510, and the first extra-contact plugs 510 are arranged in a row along an extending direction DR1 of the gate structure 200.

As shown in FIG. 1A and FIG. 1B, the semiconductor transistor device 10 may further include a metal layer 820 formed on the dielectric layer 700 and gate contact plugs 730 electrically connecting the gate structure 200 to the metal layer 820.

As shown in FIG. 1A and FIG. 1B, the semiconductor transistor device 10 may further include a fifth doped region 450 and a sixth doped region 460, the fifth doped region 450 is formed in the sixth doped region 460, and the fifth doped region 450 and the sixth doped region 460 surround the gate structure 200, the first doped region 410, the second doped region 420, the third doped region 430 and the fourth doped region 440. The fifth doped region 450 and the sixth doped region 460 have the second type conductivity, and the fifth doped region 450 has a lower doped concentration that that of the sixth doped region 460. The fifth doped region 450 and the sixth doped region 460 are separated from the other doped region by an isolation structure 330, and the sixth doped region 460 may be a guard ring of the device.

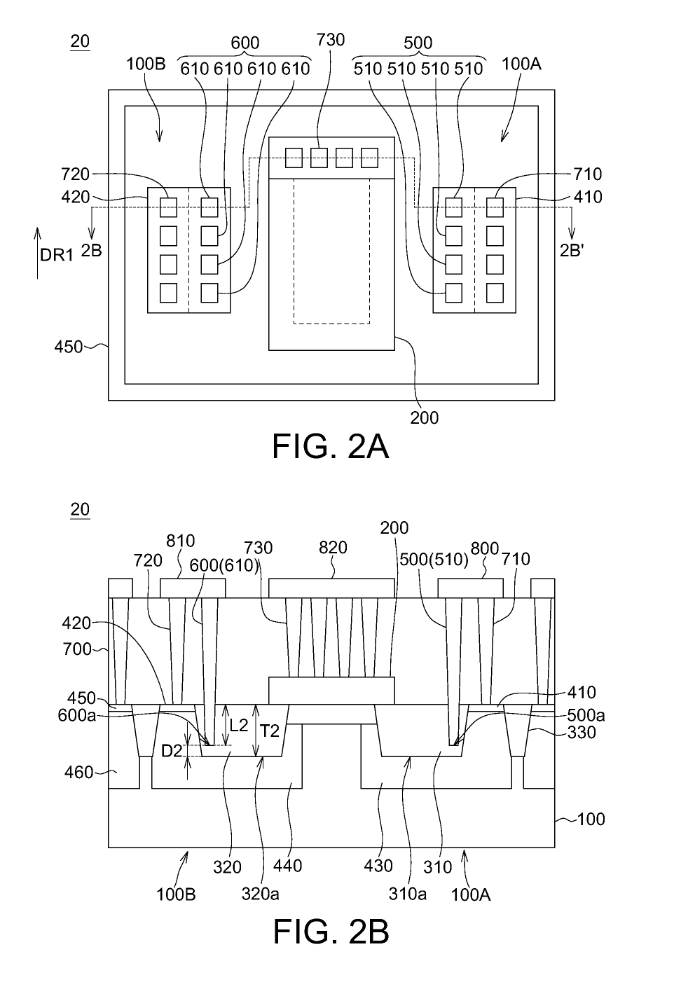

FIG. 2A shows a top view of a semiconductor transistor device according to another embodiment of the present disclosure, and FIG. 2B shows a cross-sectional view along the cross-sectional line 2B-2B′ in FIG. 2A. The elements in the present embodiment sharing similar or the same labels with those in the previous embodiment are similar or the same elements, and the description of which is omitted.

As shown in FIG. 2A and FIG. 2B, the semiconductor transistor device 20 may further include a second extra-contact structure 600, and the second extra-contact structure 600 is disposed on the semiconductor substrate 100. As shown in FIG. 2A and FIG. 2B, in the embodiments, the second extra-contact structure 600 is located between the gate structure 200 and the second doped region 420, and the second extra-contact structure 600 is penetrating into the second isolation structure 320 in the second region 100B of the semiconductor substrate 100.

In the embodiments, the second extra-contact structure 600 is electrically isolated from the gate structure 200.

In the embodiments, the second extra-contact structure 600 is electrically coupled to the second doped region 420. As shown in FIG. 2B, the semiconductor transistor device 20 may further include a metal layer 810 formed on the dielectric layer 700 and at least a contact plug 720 formed in the dielectric layer 700, and the contact plug 720 electrically connects the second doped region 420 to the metal layer 810, thereby the second doped region 420 is electrically connected to the second extra-contact structure 600 through the metal layer 810 and the contact plug 720.

As shown in FIG. 2B, in the embodiments, a bottom surface 600a of the second extra-contact structure 600 is embedded in the second isolation structure 320, and the bottom surface 600a is spaced apart from a bottom edge 320a of the second isolation structure 320 by a distance D2 of at least 70 nm.

As shown in FIG. 2B, in the embodiments, a portion of the second extra-contact structure 600 is embedded in the second isolation structure 320, the embedded portion has a second depth L2, the second isolation structure 320 has a second thickness T2, and a ratio (L2/T2) of the second depth L2 to the second thickness T2 is, for example, larger than 0.5 and less than 0.8.

As shown in FIG. 2A, in the embodiments, the second extra-contact structure 600 may include a plurality of second extra-contact plugs 610, and the second extra-contact plugs 610 are arranged in a row along the extending direction DR1 of the gate structure 200.

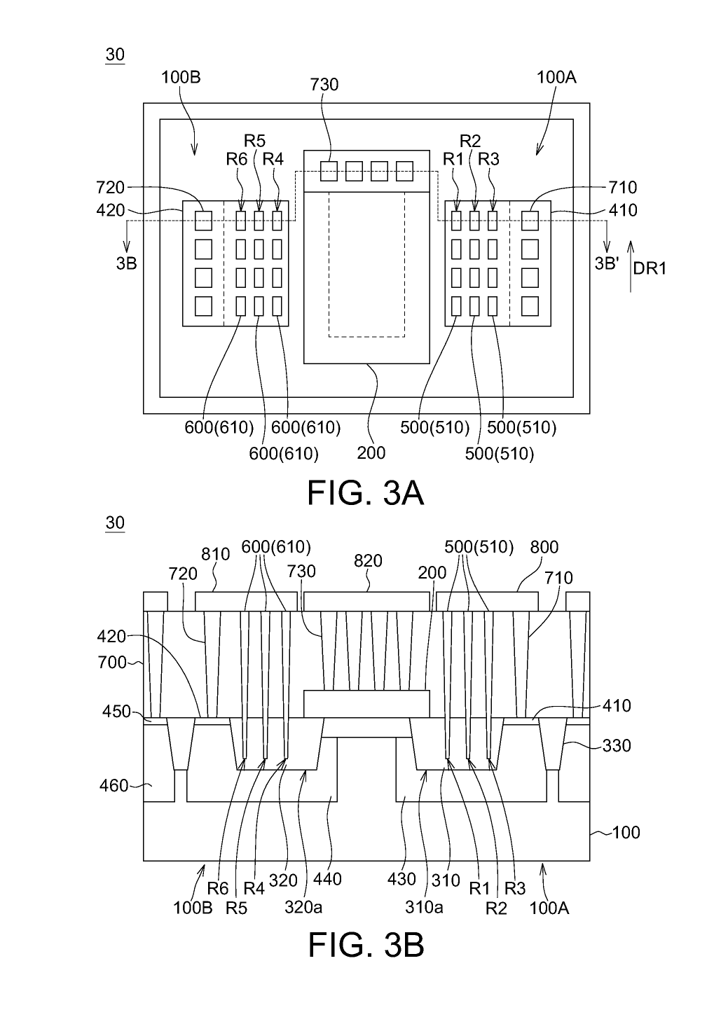

FIG. 3A shows a top view of a semiconductor transistor device according to a further embodiment of the present disclosure, and FIG. 3B shows a cross-sectional view along the cross-sectional line 3B-3B′ in FIG. 3A. The elements in the present embodiment sharing similar or the same labels with those in the previous embodiments are similar or the same elements, and the description of which is omitted.

As shown in FIG. 3A and FIG. 3B, in the semiconductor transistor device 30, the first extra-contact structure 500 may include a plurality of first extra-contact plugs 510, and the first extra-contact plugs 510 may be further arranged in a plurality of rows R1-R3 along the extending direction DR1 of the gate structure 200. In the present embodiment, three rows of the first extra-contact plugs 510 are taken as an example; however, the number of rows may vary according to actual needs and is not limited thereto.

As shown in FIG. 3A and FIG. 3B, in the semiconductor transistor device 30, the second extra-contact structure 600 may include a plurality of second extra-contact plugs 610, and the second extra-contact plugs 610 may be further arranged in a plurality of rows R4-R6 along the extending direction D1 of the gate structure.

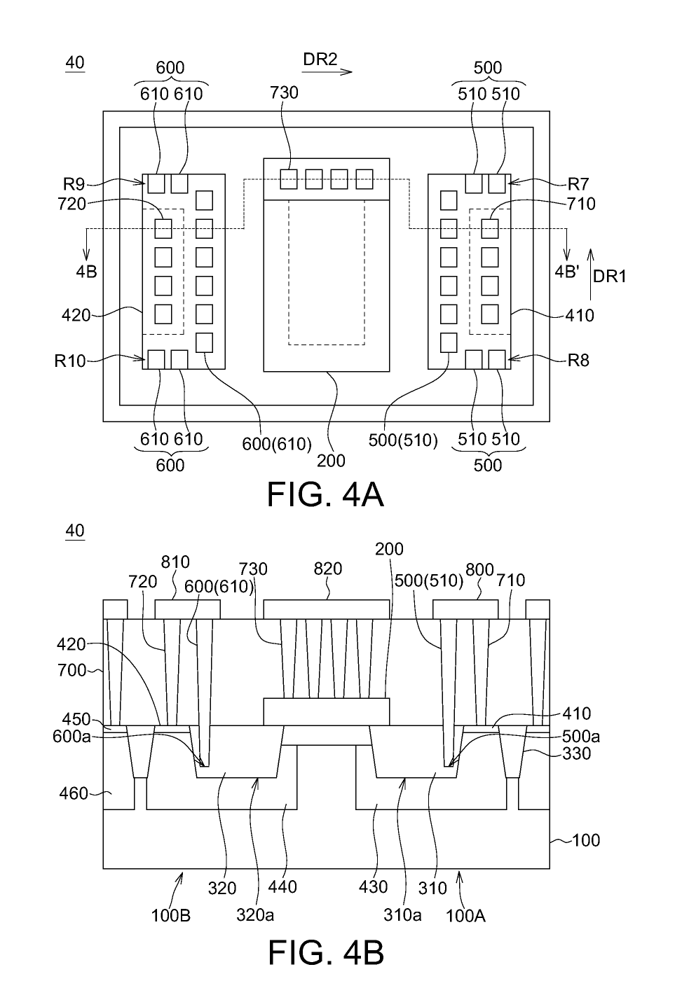

FIG. 4A shows a top view of a semiconductor transistor device according to an additional embodiment of the present disclosure, and FIG. 4B shows a cross-sectional view along the cross-sectional line 4B-4B′ in FIG. 4A. The elements in the present embodiment sharing similar or the same labels with those in the previous embodiments are similar or the same elements, and the description of which is omitted.

As shown in FIG. 4A and FIG. 4B, in the semiconductor transistor device 40, the first extra-contact structure 500 may include a plurality of first extra-contact plugs 510, and the first extra-contact plugs 510 may be further arranged in a plurality of rows R7-R8 along a direction DR2 perpendicular to the extending direction DR1 of the gate structure 200.

As shown in FIG. 4A, the first extra-contact plugs 510 of the first extra-contact structure 500 are arranged as to include a row along the extending direction DR1 and two rows R7 and R8 along the direction DR2 located on two opposite sides of the first doped region 410, the three rows forming a U-shaped arrangement surrounding three sides of the first doped region 410. While the channel region underneath the gate structure 200 is protruded outwards from the two opposite sides of the first doped region 410 along the direction DR2, the two rows R7 and R8 of the first extra-contact plugs 510 can further block the abnormal current from the drain region to the substrate, and thus Kirk effect is further prevented.

As shown in FIG. 4A and FIG. 4B, in the semiconductor transistor device 40, the second extra-contact structure 600 may include a plurality of second extra-contact plugs 610, and the second extra-contact plugs 610 may be further arranged in a plurality of rows R9-R10 along the direction DR2 perpendicular to the extending direction DR1 of the gate structure 200.

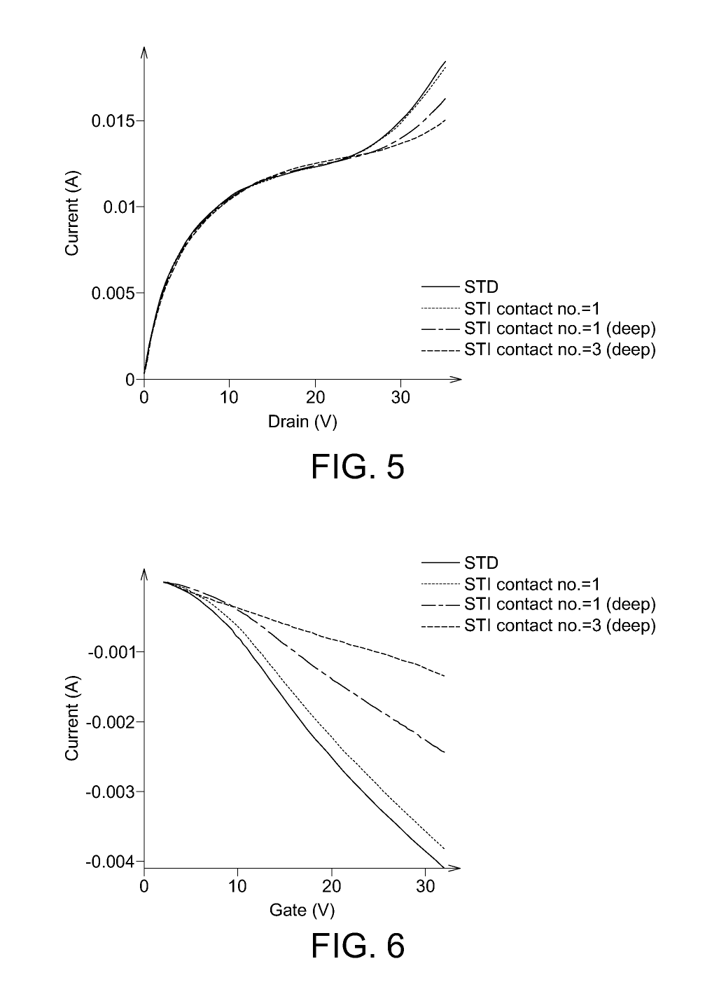

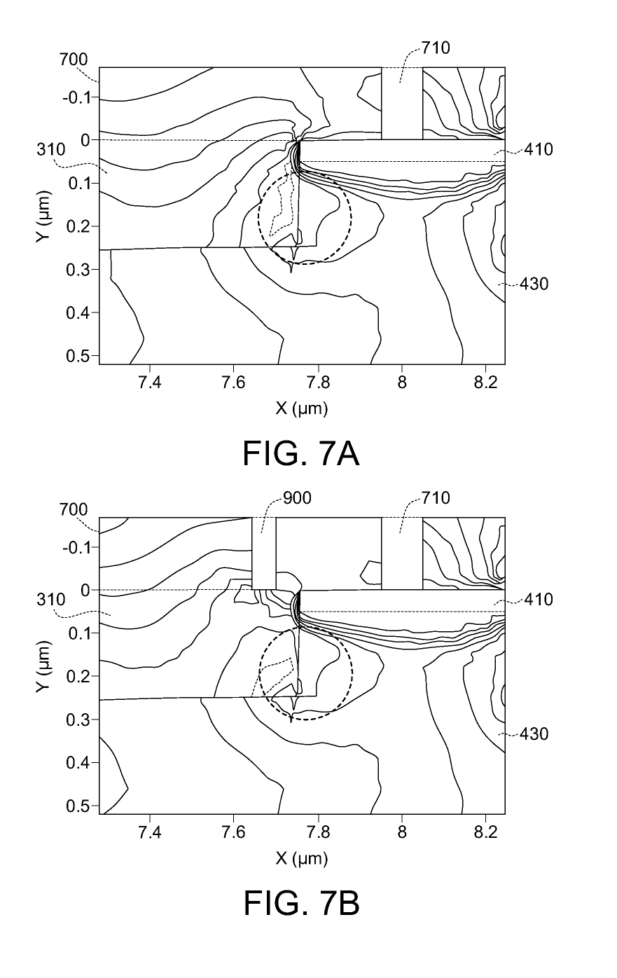

FIG. 5 shows I_{D}-V_{D} curves of semiconductor transistor devices according to some embodiments and comparative embodiments of the present disclosure, and FIG. 6 shows I_{SUB}-V_{G} curves (V_{G}=V_{D}=V_{CC}) of semiconductor transistor devices according to some embodiments and comparative embodiments of the present disclosure. Curve “STD” refers to a device without any extra-contact structure (comparative embodiment 1), curve “STI contact no.=1” refers to a device with an extra-contact structure formed in the dielectric layer 700 without penetrating into the first isolation structure 310 (comparative embodiment 2), curve “STI contact no.=1 (deep)” refers to the semiconductor transistor device 10 with an embedded depth L1 of 0.18 μm (embodiment 1), and curve “STI contact no.=3 (deep)” refers to the semiconductor transistor device 30 with an embedded depth L1 of 0.18 μm (embodiment 2).

As shown in FIG. 5 and FIG. 6, Kirk effect is clearly observed in the semiconductor transistor devices of comparative embodiments 1 and 2, and the semiconductor transistor devices of embodiments 1 and 2 show Kirk effect reductions.

Table 1 below shows data and results of electric performances of the above semiconductor transistor devices of embodiments 1-2 and comparative embodiments 1-2.

TABLE 1

| | Comparative | Comparative | | |
|---|---|---|---|---|
| | embodiment 1 | embodiment 2 | Embodiment 1 | Embodiment 2 |
| Threshold | 1.64 | 1.63 | 1.64 | 1.63 |
| voltage (V_{TO}) | | | | |
| (V) | | | | |
| Drain to source | 366 | 363 | 326 | 301 |
| current (I_{DS}) | | | | |
| (μA/μm) | | | | |
| Off current | 0.01 | 0.01 | 0.01 | 0.01 |
| (I_{OFF}) (ρA) | | | | |
| Breakdown | 39.9 | 39.2 | 39.1 | 39.1 |
| voltage (BVD) | | | | |
| (V) | | | | |
| Substrate | 370 | 362 | 326 | 302 |
| current (I_{SUB}) | | | | |
| (μA/μm) | | | | |
| (V_{G} = V_{D} = 1.1 V_{CC}) | | | | |
| I_{SUB} reduction | 0.0% | −2.2% | −13.5% | −22.5% |
| (%) | | | | |

As shown in table 1, with the design of the first extra-contact structure 500 described in the present disclosure, Kirk effect can be perfectly prevented without sacrificing the device performances. For example, the threshold voltages, the breakdown voltages and the off currents are not influenced, and the I_{SUB} is greatly reduced.

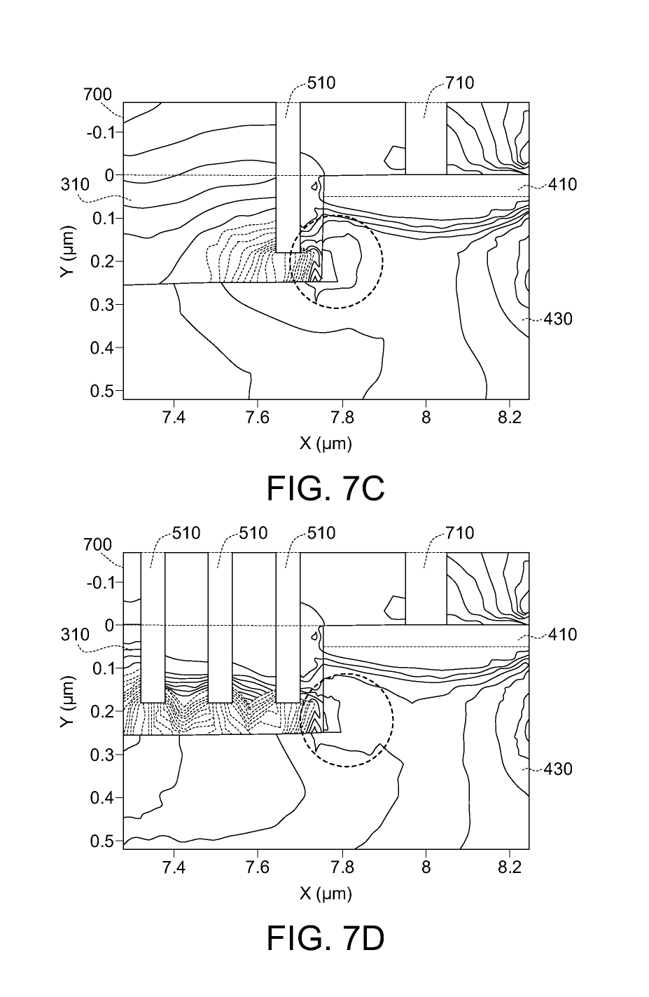

FIG. 7A to FIG. 7D show electric field distributions of semiconductor transistor devices according to some embodiments and comparative embodiments of the present disclosure. FIG. 7A and FIG. 7B refer to the aforementioned comparative embodiments 1 and 2, and FIG. 7C and FIG. 3D refer to the aforementioned embodiments 1 and 2.

As shown in FIG. 7A to FIG. 7D, the density of electric field distribution at the interface (indicated by dashed circles) between the shallow trench isolation (i.e. the first isolation structure 310) and the drain region (i.e. the first doped region 410 and the third doped region 430) is the highest in FIG. 7A and FIG. 7B, wherein the structure as shown in FIG. 7B is provided with an extra contact structure 900 without penetrating into the first isolation structure 310. In contrast, as shown in FIGS. 7C and 7D, with the design of the first extra-contact structure 500 electrically coupled to the first doped region 410 and penetrating into the first isolation structure 310, the density of electric field distribution at the interface between the shallow trench isolation and the drain region is greatly reduced, and thus Kirk effect is excellently prevented.

While the disclosure has been described by way of example and in terms of the preferred embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor transistor device, comprising:
a semiconductor substrate;
a gate structure disposed on the semiconductor substrate, wherein the semiconductor substrate has a first region and a second region respectively located on two opposite sides of the gate structure;
a first isolation structure disposed in the first region of the semiconductor substrate;
a first doped region disposed in the first region of the semiconductor substrate; and
a first extra-contact structure disposed on the semiconductor structure, wherein the first extra-contact structure is located between the gate structure and the first doped region and penetrating into the first isolation structure in the first region of the semiconductor substrate, and the first doped region is electrically coupled to the first extra-contact structure.

2. The semiconductor transistor device according to claim 1, further comprising:
a dielectric layer disposed on the semiconductor substrate; and
a metal layer disposed on the dielectric layer, wherein the first doped region is electrically coupled to the first extra-contact structure through the metal layer.

3. The semiconductor transistor device according to claim 1, wherein the first extra-contact structure comprises a plurality of first extra-contact plugs arranged in a row along an extending direction of the gate structure.

4. The semiconductor transistor device according to claim 1, wherein the first extra-contact structure comprises a plurality of first extra-contact plugs arranged in a plurality of rows along an extending direction of the gate structure.

5. The semiconductor transistor device according to claim 1, wherein the first extra-contact structure comprises a plurality of first extra-contact plugs arranged in a plurality of rows along a direction perpendicular to an extending direction of the gate structure.

6. The semiconductor transistor device according to claim 1, wherein a bottom surface of the first extra-contact structure embedded in the first isolation structure is spaced apart from a bottom edge of the first isolation structure by at least 70 nm.

7. The semiconductor transistor device according to claim 1, wherein a portion of the first extra-contact structure embedded in the first isolation structure has a first depth, the first isolation structure has a first thickness, and a ratio of the first depth to the first thickness is larger than 0.5 and less than 0.8.

8. The semiconductor transistor device according to claim 1, further comprising:
a second isolation structure disposed in the second region of the semiconductor substrate; and
a second doped region disposed in the second region of the semiconductor substrate.

9. The semiconductor transistor device according to claim 8, wherein the first doped region and the second doped region have a first conductive type.

10. The semiconductor transistor device according to claim 8, further comprising:
a second extra-contact structure disposed on the semiconductor substrate, wherein the second extra-contact structure is located between the gate structure and the second doped region and penetrating into the second isolation structure in the second region of the semiconductor substrate.

11. The semiconductor transistor device according to claim 10, wherein the second extra-contact structure is electrically coupled to the second doped region.

12. The semiconductor transistor device according to claim 10, wherein the second extra-contact structure comprises a plurality of second extra-contact plugs arranged in a row along the extending direction of the gate structure.

13. The semiconductor transistor device according to claim 10, wherein the second extra-contact structure comprises a plurality of second extra-contact plugs arranged in a plurality of rows along the extending direction of the gate structure.

14. The semiconductor transistor device according to claim 10, wherein the second extra-contact structure comprises a plurality of second extra-contact plugs arranged in a plurality of rows along a direction perpendicular to the extending direction of the gate structure.

15. The semiconductor transistor device according to claim 10, wherein a bottom surface of the second extra-contact structure embedded in the second isolation structure is spaced apart from a bottom edge of the second isolation structure by at least 70 nm.

16. The semiconductor transistor device according to claim 10, wherein a portion of the second extra-contact structure embedded in the second isolation structure has a second depth, the second isolation structure has a second thickness, and a ratio of the second depth to the second thickness is larger than 0.5 and less than 0.8.

17. The semiconductor transistor device according to claim 8, further comprising:
a third doped region encompassing the first doped region and the first isolation structure, wherein the first doped region and the third doped region have a first conductive type, and a doped concentration of the first doped region is higher than a doped concentration of the third doped region.

18. The semiconductor transistor device according to claim 17, further comprising:
a fourth doped region encompassing the second doped region and the second isolation structure, wherein the second doped region and the fourth doped region have the first conductive type, and a doped concentration of the second doped region is higher than a doped concentration of the fourth doped region.

19. The semiconductor transistor device according to claim 1, wherein the semiconductor substrate has a second conductive type.
